(19) United States
(12) Patent Application Publication
(10) Pub. No.: US 2023/0313014 A1
(43) Pub. Date: Oct. 5, 2023

(54) ALKYLMETHYLSILOXANE LIQUID IMMERSION COOLING MEDIA

(71) Applicants: Dow Global Technologies LLC, Midland, MI (US); Dow Silicones Corporation, Midland, MI (US); Dow Toray Co., Ltd., Tokyo (JP)

(72) Inventors: Zhengming Tang, Shanghai (CN); Shreyas Bhide, Navi Mumbai (IN); Hongyu Chen, Shanghai (CN); Peng Wei, Shanghai (CN); Patricia Ansems Bancroft, Freeport, TX (US); Zhihua Liu, Shanghai (CN); Son Phan, Ichihara-City (JP)

(21) Appl. No.: 18/006,039

(22) PCT Filed: Oct. 14, 2021
(86) PCT No.: PCT/CN2021/123732

§ 371 Date: Jan. 19, 2023

(30) Foreign Application Priority Data
Oct. 28, 2020 (WO) PCT/CN2020/124314

(51) Int. Cl. C09K 5/10; C08G 77/38; C08G 77/04; H05K 7/20

(52) U.S. Cl. CPC C09K 5/10; C08G 77/045; C08G 77/38; H05K 7/20236; H05K 7/20263; H05K 7/20772; H05K 7/20272

(57) ABSTRACT

A process includes immersing a device in a cooling fluid, the cooling fluid comprising an alkyl modified silicone oil having the following average chemical structure (I) : (CH ₃) ₃SiO- [ (CH ₃) ₂) SiO] ₘ- [R (CH ₃) SiO] ₙ-Si (CH ₃) ₃ (I) where: R in each occurrence is an alkyl or substituted alkyl having 6 or more and at the same time 17 or fewer carbon atoms; subscript m has a value of one or higher and at the same time less than 22, subscript n has a value of one or higher, and the sum of m+n is greater than 5 and at the same time less than 50.

### FIELD OF THE INVENTION

The present invention relates to processes and systems using immersion cooling fluid containing alkylmethylsiloxane.

### INTRODUCTION

As data center equipment becomes more powerful they generate more heat, which can inhibit the lifespan and performance of the data center equipment. Circulating air has been used to remove heat from data center equipment. However, circulating air is not efficient enough to adequately cool newer and more powerful equipment. More recently, heat transfer fluids circulating within enclosed paths through data center equipment has been used to remove heat from the equipment. The fluid does not directly contact the equipment but rather flows through fluid conduits within the equipment. This is considered “indirect” fluid cooling of the equipment. Circulating enclosed fluids can be more efficient at heat removal than circulating air, but still is not as efficient as is desired.

Most recently, “direct” fluid cooling of data center equipment has been introduced as a more efficient cooling means for the data center equipment. Direct fluid cooling uses fluid coolant in direct contact with data center equipment to cool the equipment. Typically, the equipment is immersed in fluid coolant that is often circulated around and through the equipment. This is an efficient means for cooling the equipment. However, there are challenges with bringing electronic equipment in direct contact with fluids. Direct fluid cooling is a specialized application that requires rather specialized cooling fluid. Ideally, the cooling fluid is thermally conductive and also highly dielectric (that is, a poor electrical conductor). It is also important that the cooling fluid be compatible with the equipment with which it comes in contact ― that is, the cooling fluid should not degrade, modify, or otherwise impact the equipment with which it comes in contact. It is also desirable for the fluid to be environmentally safe such as, for example, having a low flammability and low toxicity.

Perhaps the most dominant fluid on the market for use as a direct cooling fluid for data center equipment are fluorinated materials, such as those sold under the name 3M™ Fluorinert™ Electronic Liquids and 3M™ Novec™ Engineered Fluids from 3 M. “3 M”, “Fluorinert”, and “Novec” are trademarks of 3 M Company. These fluorinated materials tend to be efficient in heat removal. However, these fluorinated materials have a relatively low boiling point (less than 200 degrees Celsius (°C), most below 150° C.). The low boiling point of the fluorinated materials limits their application to temperatures below 175° C. according to their advertising literature. The low boiling point also means that they evaporate relatively easily, which can undesirably result in exposing operators and the environment to fluorinated materials.

Mineral oil is another fluid that can be used as a direct cooling fluid for data center equipment. Mineral oil is desirable because it is inexpensive. However, it also has significant challenges for a direct cooling fluid application. Mineral oil only is moderately efficient in heat removal and typically includes impurities such as sulfur, which can cause corrosion of the data center equipment. Concerns with the flammability of mineral oil and degradation of mineral oil over time also have been noted. Moreover, mineral oil tends to swell ethylene propylene diene monomer (EPDM) rubber, which can result in failure of capacitors in servers and ultimately the server when used as a direct cooling fluid in contact with the capacitors. Therefore, there is risk of damage to electronic data center equipment exposed to mineral oil as a direct cooling fluid.

Polyalphaolefin (PAO) synthetic oils are yet another option for direct cooling fluids. While generally having fewer impurities than mineral oil, there are still concerns with PAO synthetic oils regarding flammability and degradation over time. Like mineral oil, PAO also tends to swell EPDM rubber so there is a risk of damage to electronic data center equipment exposed to PAO synthetic oil as a direct cooling fluid.

Polydimethylsiloxane (PDMS) is another option as a direct cooling fluid that offers a lower cost option relative to fluorinated fluids, good compatibility with non-silicone components of data center equipment, relatively low flammability, and high stability against degradation. However PDMS tends to swell silicone rubber materials and weaken the peel strength of silicone rubber adhesive materials resulting in easier delamination of component adhered with silicone rubber. Silicone-based materials are often used in electronic devices as heat conductive grease and gap fillers to thermally couple components. Swelling of these materials can results in delamination of these materials from the thermally coupled components, thereby decreasing the thermal coupling and heat transfer between thermally conductive components.

It is desirable to identify a cooling fluid for the specialized application of a direct cooling fluid for cooling electronic data center equipment. The cooling fluid should avoid the challenges of fluorinated fluids, mineral oil, PAO synthetic oil and PDMS. In particular, it is desirable to identify a direct cooling fluid that has the following characteristics:
is liquid at 25° C. and 101 kiloPascals pressure (760 millimeters mercury pressure);
has a kinematic viscosity of less than 100 square millimeters per second (mm²/s) at 25° C.;
does not significantly swell or imbibe EPDM or silicone rubber;
has a flash point of greater than 150° C.; and
can be free of halogens,

### BRIEF SUMMARY OF THE INVENTION

The present invention provides a direct contact (immersion) cooling process and system that uses a cooling fluid suitable for direct cooling application such as including electronic data center equipment. The fluid surprisingly simultaneously has the following characteristics: (i) is a liquid at 25° C. and 101 kiloPascals (kPa) pressure; (ii) has a kinematic viscosity of less than 100 mm²/s at 25° C.; (iii) does not significantly swell or imbibe EPDM or silicone rubber; (iv) has a flash point of greater than 150° C.; and (v) can be free of halogens.

The cooling fluid of the present invention comprises an alkyl modified PDMS (“alkylmethylsiloxane”). A concern with alkylmethylsiloxanes in direct cooling systems can be residual silyl hydride (SiH) and free hydrocarbon component. Residual SiH is undesirable because it tends to hydrolyze to silanol (SiOH) and release hydrogen gas. Production of hydrogen gas in the presence of electronic components is an undesirable safety risk. The presence of silanol is a polar group that negatively impacts the dielectric property of the siloxane, making it less efficient as a direct cooling fluid. Free hydrocarbon components can cause phase haziness or even phase separation in a cooling fluid and can increase swelling or imbibing of EPDM rubber. Surprisingly, the alkylmethylsiloxane of the present invention not only achieves the fluid characteristic mentioned in the prior paragraph but also has an SiH concentration where the hydrogen for the SiH groups is less than 10 weight-parts per million (ppm) based on alkylmethylsiloxane weight and a free hydrocarbon concentration below 20 weight-percent (wt%) based on alkylmethylsiloxane weight.

In a first aspect, the present invention is a process comprising the step of immersing a device in a cooling fluid, the cooling fluid comprising an alkyl modified silicone oil having the following average chemical structure (I):

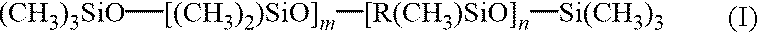

where: R in each occurrence is an alkyl or substituted alkyl, where the R group has 6 or more and at the same time 17 or fewer carbon atoms; subscript m has a value of one or higher and at the same time less than 22, subscript n has a value of one or higher, and the sum of m+n is greater than 5 and at the same time less than 50

EP0641849B 1 discloses use of alkylmethylsiloxane fluids as heat transfer fluids. However, the reference does not mention the specialized application of a direct cooling fluid or the benefits it offers in the specialized application of direct cooling over PDMS or other direct cooling fluids. Moreover, it has been discovered that not all alkylmethylsiloxane fluids, not even all of those taught as heat transfer fluids in EP0641849B 1, are suitable as a direct cooling fluid. In particular, polydimethylsiloxane, which has the chemical structure (I) where R is a one-carbon alkyl, is not an acceptable material because it swells and imbibes silicone rubber. Short chain alkyls for R are likely to perform similarly to polydimethylsiloxane. Examples herein show that if the R group has 6 or more carbons it is an acceptable immersion cooling fluid.

In a second aspect, the present invention is a liquid immersion cooling system comprising a device in a cooling fluid, the cooling fluid comprising an alkyl modified silicone oil having the following average chemical structure (I):

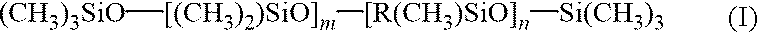

where: R in each occurrence is an alkyl or substituted alkyl having 6 or more and at the same time 17 or fewer carbon atoms; subscript m has a value of one or higher and at the same time less than 22, subscript n has a value of one or higher, and the sum of m+n is greater than 5 and at the same time less than 50.

### DETAILED DESCRIPTION OF THE INVENTION

Test methods refer to the most recent test method as of the priority date of this document when a date is not indicated with the test method number. References to test methods contain both a reference to the testing society and the test method number. The following test method abbreviations and identifiers apply herein: ASTM refers to ASTM International methods; EN refers to European Norm; DIN refers to Deutsches Institut für Normung; ISO refers to International Organization for Standards; and UL refers to Underwriters Laboratory.

Products identified by their tradename refer to the compositions available under those tradenames on the priority date of this document.

“Multiple” means two or more. “And/or” means “and, or as an alternative”. All ranges include endpoints unless otherwise indicated. Unless otherwise stated, all weight-percent (wt%) values are relative to composition weight and all volume-percent (vol%) values are relative to composition volume.

“Kinematic viscosity” for individual polysiloxanes is determined by ASTM D 445 using a glass capillary Cannon-Fenske type viscometer at 25 degrees Celsius (°C) unless otherwise stated.

Determine flash point for a material with Cleveland Open Cup (COC). Perform the COC measurement with approximately 70 milliliters of sample. Set the expected flash point at 100° C. Increase the temperature at a rate of 14-17° C. per minute from 25° C. to approximately 44° C. and then at a rate of 5 to 6° C. per minute until flash point is identified.

Determine whether a fluid “significantly swells” or “significantly imbibes” EPDM and silicone rubber using the Compatibility Test procedure set forth in the Example section below.

Determine SiH concentration for a fluid by combining 1.0 g of a Sample material and 8.0 milligrams of pyrazine (as an internal standard) with 1.5 milliliters of deuterated chloroform to get a homogeneous solution. Add a portion of the solution to a 5 millimeter nuclear magnetic resonance (NMR) tube and collect a 1H NMR spectrum at 25° C. on a Bruker AVANCE II 400 megahertz NMR instrument with a zg pulse program, D1=15 seconds and NS=32. The integrated intensity of the proton signal for SiH (single peak from 4.65-4.78 ppm) in the spectrum provides the ratio for the number of hydrogens on the Si atoms relative to pyrazine. The concentration of hydrogen on silicone atoms can be calculated relative to the total weight of Sample material.

Determine free hydrocarbon concentration for a fluid using gas phase chromatography/mass spectrometry (GC/MS). Dilute approximately 0.5 g of a fluid sample into approximately 4.5 g of toluene. Measure and record the weight of the components using an analytical balance. Analyze the diluted sample by GC/MS using standard chemicals of hydrocarbons, particularly those used as reactants in making the sample, such as 1-hexene, 1-octene, 1-dodecene, 1-tetradecene, etc. for calibration. Use an Agilent 7890A Gas Chromatography system with a DB-5ms column (30 meters × 0.25 millimeter internal diameter × 0.25 micrometers film); 1.0 milliliter per minute constant helium carrier gas flow; oven parameters of: 40° C., hold 6 minutes, 15° C./minute ramp to 280° C., hold 10 minutes for a total run time of 32.0 minutes; inject one-microliter sample via an autosampler system and 10 microliter syringe; inlet temperature is 280° C. with a split ratio of 50:1; the detector is MSD with MS source temperature of 230° C., MS Quad temperature of 150° C., Aux-2 temperature of 280° C. and Acquisition Mode: scan mass from 29 to 350.

“Alkyl” refers to a hydrocarbon radical derivable from an alkane by removal of a hydrogen atom. An alkyl can be linear or branched.

“Substituted alkyl” refers to a radical similar to an alkyl except where a non-hydrogen group resides in place of one or more than one hydrogen atom. For instance, an alkyl where one or more of the hydrogen atoms have been replaced with an aromatic group (such as phenyl or benzyl), or a halogen such as fluorine constitutes a substituted alkyl.

In a first aspect, the present invention is a process comprising immersing a device in cooling fluid. “Immersing” as used herein can refer to partially submerging the device in a cooling fluid without completely submerging or, preferably, refers to completely submerging the device in a cooling fluid. In like manner, “immerse”, “immersion” and like terms can refer to less than full submersion of a device or can refer to complete submersion of a device.

In the broadest scope of the present invention, the device can be any article. Desirably, the device is a heat generating article, or is a component affixed to a heat generating article. For instance, the device can be a heat sink affixed to (attached to) a heat generating article, can be the heat generating article or can be both a heat generating article and a heat sink affixed to the heat generating article. The present invention is particularly applicable to devices that are electronic devices. The device can be a computer or part of a computer. Herein, a “computer” refers to an electronic device that can store, retrieve, and/or process data. A “part of a computer” refers to any one or any combination of more than one component of a computer and can include, for example, any one or any combination of more than one component selected from electronic power distribution components (such as electronic transformers), servers that comprise a circuit board with a plurality of electronic component mounted thereon and residing in a housing, circuit boards themselves, electronic random access memory components, memory storage components, a central process unit (CPU) and a graphics processing unit.

The cooling fluid comprises, or can consist of, an alkyl modified silicone oil. The cooling fluid typically comprises more than 50 weight-percent (wt%), preferably 75 wt% or more, 90 wt% or more, 95 wt% or more, 98 wt% or more, even 99 wt% or more of alkyl modified silicone oil relative to cooling fluid weight. The cooling fluid can consist of alkyl modified silicone oil.

The alkyl modified silicone oil has the following average chemical structure (I):

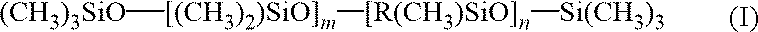

where:
R is independently in each occurrence selected from alkyl groups and substituted alkyl groups where the R group contains 6 or more, 7 or more, 8 or more, 9 or more, 10 or more, 11 or more, 12 or more, 13 or more, 14 or more, 15 or more even 16 or more while at the same time 17 or fewer, 16 or fewer, 15 or fewer, 14 or fewer, 13 or fewer, 12 or fewer, 11 or fewer, 10 or fewer, 9 or fewer, 8 or fewer, or even 7 or fewer carbon atoms; preferably R is selected from a group consisting of alkyl groups having the above-specified number of carbon atoms and substituted alkyl groups where the alkyl and the substituted group(s) on the alkyl have a combined number of carbon atoms in the specified range above. For example, the R group can be a phenyl substituted alkyl where the total number of carbon atoms is the sum of the number of alkyl carbon atoms and phenyl carbons atoms.
Subscript m has a value of one or higher, and can have a value of 2 or higher, even 3 or higher and at the same time is typically less than 22, and can be 20 or less, 15 or less, 10 or less, and can be 9 or less, 8 or less, 7 or less, 6 or less, or even 5 or less.
Subscript n has a value of one or higher, preferably 2 or more, 3 or more, 4 or more, even 5 or more while at the same time is typically less than 30, and can be 25 or less, 20 or less, 15 or less, 10 or less, 9 or less, 8 or less, 7 or less, or even 6 or less.
The sum of subscripts m and n (“m+n”) has a value of 5 or more, and can be 6 or more, 7 or more, 8 or more, 9 or more, 10 or more, 15 or more, 20 or more, and can even be 25 or more while at the same time has a value of less than 50, and can be 40 or less, 30 or less, 25 or less, 20 or less, 15 or less, 10 or less, or even 9 or less.

Determine the identity of the alkyl modified silicone oil, including identity of R groups, and values for m and n using ¹H, ¹³C and ²⁹Si nuclear magnetic resonance spectroscopy by standard methods.

The alkyl modified silicone oil has a kinematic viscosity of less than 100 square millimeters per second (mm²/s, or centiStokes (cSt)), and can have a kinematic viscosity of 75 mm²/s or less, 50 mm²/s or less, preferably 30 mm²/s or less and more preferably 20 mm²/s or less and can be 10 mm²/s or less while at the same time desirably has a kinematic viscosity of more than 5 mm²/s. Selection of R, m, and n values to achieve a kinematic viscosity in these ranges is readily achievable.

It has been discovered that the R group in chemical structure (I) desirably has 6 or more carbon atoms. When R contains fewer than 6 carbon atoms then the alkyl modified silicone oil is likely to have characteristics too similar to polydimethylsiloxane, which swells and imbibes silicone rubber. At the same time, it has been discovered that the R group in chemical structure (I) must have 17 or fewer carbon atoms because the material becomes a wax rather than a fluid at 25° C. and 101 kPa pressure when R has 18 or more carbon atoms. The R group can be substituted or non-substituted. For example, the R group can be halogenated (substituted with one or more than one halogen) or can be non-halogenated (free of halogens). Hence, the alkyl-modified silicone oil can be free of halogens and, in fact, the cooling fluid as a whole can be free of halogens. The R group can be a phenyl-substituted alkyl group where the alkyl component has fewer than 6 carbon atoms but the total number of carbon atoms in the R group is 6 is in the above-specified required range. Alternatively, the R group can be an alkyl group having a number of carbons in the above-specified required range. The R group can be linear or branched. Branched structures can be desirable to lower the melting point of an alkyl modified silicone oil.

The alkyl modified silicone oil must have a value for subscript n that is one or more or it is not an alkyl modified silicone oil but rather polydimethylsiloxane.

The value for m+n is limited by the desire for the alkyl modified silicone oil to have a kinematic viscosity in the range as stated above.

Particularly desirably alkyl modified silicone oils are selected from a group consisting of any one or any combination or more than one alkyl modified silicone oils having chemical structure (I) where: m is 3, n is 6 and R is a linear alkyl group having from 6 to 16 carbon atoms; m is 5, n is 3 and R is a linear alkyl having 10 carbon atoms; and m is 3, n is 4 and R is a 3-carbon alkyl with the middle carbon substituted with a phenyl group.

The alkyl modified silicone oils can be synthesized by hydrosilylation reactions as described in the Examples section below.

The cooling fluid can comprise or consist of the alkyl modified silicone oil, or even a combination of more than one of the alkyl modified silicone oils. Alternatively, the cooling fluid can comprise or consist of a mixture of alkyl modified silicone oil(s) and one or more than one additional fluid that satisfies the requirements of an immersion cooling fluid. For instance, the cooling fluid can comprise the alkyl modified silicone oil and a fluorocarbon fluid provided the fluorocarbon fluid has a boiling point of greater than 150° C.

Desirably, the cooling fluid comprises less than 20 weight-percent (wt%) free hydrocarbons, preferably 10 wt% or less, 5 wt% or less, one wt% or less and can be free of free hydrocarbons where wt% hydrocarbons is relative to alkyl modified silicone oil weight. “Free hydrocarbons” refer to hydrocarbons that are not chemically bound to a non-hydrocarbon component (for example, an alkyl on a siloxane molecule is not a “free hydrocarbon” but hexane or 1-hexene would be). It is desirable to minimize free hydrocarbons because they can contribute to swelling of organic materials like EPDM rubber. Free hydrocarbons can also lower the flash point of a composition.

Desirably, the alkyl modified silicone oil contains minimal if any SiH functionality. Determine extent of SiH functionality by measuring the wt% of H from SiH functionalities relative to alkyl modified silicone oil weight. The wt% of H is desirably less than 10 weight-parts per million weight parts (ppm), preferably 9 ppm or less, 9 ppm or less, 7 ppm or less, 6 ppm or less, 6 ppm or less, 5 ppm or less, 4 ppm or less, 3 ppm or less, 2 ppm or less one ppm or less with ppm relative to alkyl modified silicone oil weight. The alkyl modified silicone oil can be free of SiH functionality.

The cooling fluid can contain any one or any combination of more than one option components such antioxidants. Antioxidants can be desirable to increase the thermal stability of the cooling fluid, especially antioxidants that stabilize the alkyl group. Suitable antioxidants typically are aromatic amines and/or hindered phenolics. Examples of suitable antioxidants include those selected from a group consisting of those available under the following trade names: IRGANOX™ 1076 and IRGANOX™ 1010. IRGANOX is a trademark of BASF SE company.

The process of the present invention comprises immersing a device in a cooling fluid that comprises or consists of the alkyl modified silicone oil and can further include one or more than one additional steps. For instance, the process can include cooling the cooling fluid (the alkyl modified silicone oil). For example, the cooling fluid can be stationary within container with a device immersed in the cooling fluid while the container refrigerates the cooling fluid. The cooling fluid can be circulated around a device immersed in the cooling fluid within a container (a circulating bath) where the container refrigerates the cooling fluid. The cooling fluid can be cooled in a separate cooling unit and circulated between the cooling unit and a container in which the device immersed in the cooling fluid resides such that the cooling fluid circulates around the device, through the cooling unit and then back around the device in a cycle.

In another aspect, the present invention is a liquid immersion cooling system. In this context, a “system” refers to a collection of components that are associated with one another in such a way so as to achieve a specific purpose. In the present invention, the liquid immersion cooling system comprises components that serve to accomplish the immersion cooling of a device immersed in a cooling fluid.

Liquid immersion cooling systems of varying complexity are known in the industry and the broadest scope the present invention includes any immersion cooling system.

The system of the present invention comprises a device in a cooling fluid, where the cooling fluid comprises or consists of the alkyl modified silicone oil described herein. The device is as described above herein.

The system can further comprise a cooler that removes heat from the cooling fluid. The cooler can be a refrigerated container in which the cooling fluid resides to form a cooling bath in which the device is immersed. The system can further comprise a circulating component that causes the cooling fluid to flow around the device that is immersed therein. The circulating component can be an impeller submerged in the cooling fluid that causes flow of the fluid around the immersed device while the fluid and device reside in a single container that may or may not be a cooler. Alternatively, or additionally, the circulating component can be a circulating pump or other circulating component that flows cooling fluid between a container containing the cooling fluid and a device immersed in the cooling fluid and another container or device that cools the cooling fluid in a cycle.

Notably, the cooling fluid is desirably in direct contact with the device immersed in the cooling fluid in both the process and system of the present invention.

### EXAMPLES

Table 1 presents the materials for use in the following examples. DOWSIL, XIAMETER and NORDEL are a trademarks of The Dow Chemical Company. SpectraSyn is a trademark of Exxon Mobil Corporation. Ultra-S is a trademark of S-Oil Corporation.

TABLE 1

| | | |
|---|---|---|
| Component | Description | Source |
| Pt-47D Catalyst | A mixture of 20 wt% tetramethyldivinyldisiloxane, 70 wt% isopropanol and 10 wt%)1,3-diethyl-1,1,3,3-tetramethyldisiloxane complex of platinum) | Available from The Dow Chemical Company as PT-47D. |
| Trifluoromethane sulfonic acid | Trifluoromethane sulfonic acid | Sigma-Aldrich |
| Trimethylsiloxy terminated methylhydrogen polysiloxane 1 | SiH content of 1.6 wt% and viscosity of 15-20 mm²/s | Available as HMS-991 from Gelest |
| Trimethylsiloxy terminated methylhydrogen polysiloxane 2 | SiH content of 1.6 wt% and viscosity of 30-45 mm²/s | Available as HMS-993 from Gelest |
| Hexamethyldisiloxane | (CH₃)₃SiOSi(CH₃)₃ | Sigma-Aldrich |
| Octamethylcyclotetrasil oxane | [(CH₃)₂SiO]₄ | Sigma-Aldrich |
| 1-Hexene | 1-hexene | SCRC reagent company |
| 1-Octene | 1-octene | SCRC reagent company |
| 1-Tetradecene | 1-Tetradecene | SCRC reagent company |
| 1-Hexadecene | 1-Hexadecene | SCRC reagent company |
| 1-Octadecene | 1-Octadecene | SCRC reagent company |
| 1-Decene | | Sigma-Aldrich |
| Alpha-methyl styrene | Alpha-methyl styrene | Fujifilm Wako Pure Chemical corporation. |
| MD(C₈H₁₇)M | (CH₃)₃SiO(C₈H₁₇)(CH₃)SiOSi(CH₃)₃ | Available as TM-081 from Gelest. |
| PAO Oil | Polyalphaolefin having a kinematic viscosity of 48 mm²/s at 40° C., flash point of 500° C., Brookfield viscosity at -40° C. of 17590 centiPoise per ASTMD2983. | Available as SpectraSyn™ 8 PAO fluid from Exxon Mobil. |
| Mineral Oil | Natural hydrocarbon-based oil with a specific gravity of 0.847, kinetic viscosity at 40° C. of 43.89 mm²/s, flash point of 256° C., and pour point of -15.0° C. | Available as Ultra-S™ 8 (250N) lube base oil from S-oil. |
| PDMS | Polydimethylsiloxane having a kinematic viscosity of 20 mm²/s. | Available as Fluid 200, 20 mm²/s from The Dow Chemical Company. |
| Fluorocarbon Fluid 1 | Linear fluorocarbon | Available as F-601 from Juhua Chemical |
| Silicone Rubber | A 50 Durometer, translucent, non-catalyzed silicone rubber base. | Available as XIAMETER™ RBB-2002-50 Base from The Dow Chemical Company |
| EPDM Rubber | A film of a blended material that is 70 wt% medium viscosity, medium ethylene propylene-diene terpolymer (density 0.87 g/cm3) and 30 wt% amorphous ethylene-propylene-diene grade polymer (density 0.86 g/cm3 density, 50 wt% ethylene content). | A mixture of 70 wt% NORDEL™ 3765 XFL EPDM and 30 wt% NORDEL™ 4520 EPDM that is compression molded on a hot press for 5 minutes at 180° C. |

### SiH Siloxanes and Synthesis Methods

### SiH Siloxane 1: (CH₃)₃SiO[H(CH₃)SiO]₁Si(CH₃)₃

Prepare by trifluoromethane sulfonic acid catalyzed equilibration of 70 wt% hexamethyldisiloxane and 30 wt% trimethylsiloxy terminated methylhydrogen polysiloxane 2 as described in US20060264602A1 and art cited therein.

### SiH Siloxane 2: (CH₃)₃SiO[(CH₃)₂Si)]₃[H(CH₃)SiO]ₛSi(CH₃)₃

Prepare by trifluoromethane sulfonic acid catalyzed equilibration of 14.9 wt% hexamethyldisiloxane and 62.9 wt% octamethylcyclotetrasiloxane and 22.2 wt% trimethylsiloxy terminated methylhydrogen polysiloxane 2 as described in US20060264602A1 and art cited therein.

### SiH Siloxane 3: (CH₃)₃SiO[H(CH₃)SiO]₁₇Si(CH₃)₃

Prepare by trifluoromethane sulfonic acid catalyzed equilibration of 10.11 wt% hexamethyldisiloxane and 89.89 wt% trimethylsiloxy terminated methylhydrogen polysiloxane 2 as described in US20060264602A1 and art cited therein.

### SiH Siloxane 4: (CH₃)₃SiO[(CH₃)₂Si)]₃[H(CH₃)SiO]₆Si(CH₃)₃

Prepare by trifluoromethane sulfonic acid catalyzed equilibration of 18.8 wt% hexamethyldisiloxane, 31.9 wt% of octamethylcyclotetrasiloxane and 49.3 wt% trimethylsiloxy terminated methylhydrogen polysiloxane 2 as described in US20060264602A1 and art cited therein.

### SiH Siloxane 5: (CH₃)₃SiO[(CH₃)₂Si)]_{22[}H(CH₃)SiO]₂Si(CH₃)₃

Prepare by trifluoromethane sulfonic acid catalyzed equilibration of 8.26 wt% hexamethyldisiloxane, 84.91 wt% of octamethylcyclotetrasiloxane and 6.83 wt% trimethylsiloxy terminated methylhydrogen polysiloxane 2 as described in US20060264602A1 and art cited therein.

### SiH Siloxane 6: (CH₃)₃SiO[(CH₃)₂Si)]₁₆[H(CH₃)SiO]₃₈Si(CH₃)₃

Prepare by trifluoromethane sulfonic acid catalyzed equilibration of 1.81 wt% hexamethyldisiloxane, 32.41 wt% of octamethylcyclotetrasiloxane and 65.78 wt% trimethylsiloxy terminated methylhydrogen polysiloxane 2 as described in US20060264602A1 and art cited therein.

### SiH Siloxane 7: (CH₃)₃SiO[(CH₃)₂Si)]₃₅[H(CH₃)SiO]₃₅Si(CH₃)₃

Prepare by trifluoromethane sulfonic acid catalyzed equilibration of 7.11 wt% polydimethylsiloxane fluid (available as DOWSIL™ SH 200 fluid 10 cSt from The Dow Chemical Company), 47.15 wt% of octamethylcyclotetrasiloxane and 45.74 wt% trimethylsiloxy terminated methylhydrogen polysiloxane 1 as described in US20060264602A1 and art cited therein.

### SiH Siloxane 8: (CH₃)₃SiO[(CH₃)₂Si)]₂₅[H(CH₃)SiO]₅₅Si(CH₃)₃

Prepare by trifluoromethane sulfonic acid catalyzed equilibration of 34.25 wt% dimethylsiloxane cyclics (available as DOWSIL™ 344 Fluid from The Dow Chemical Company) and 64.75 wt% trimethylsiloxy terminated methylhydrogen polysiloxane 1 as described in US20060264602A1 and art cited therein.

### SiH Siloxane 9: (CH₃)₃SiO[(CH₃)₂Si)]₈₄[H(CH₃)SiO]₁₄Si(CH₃)₃

Prepare by trifluoromethane sulfonic acid catalyzed equilibration of 1.76 wt% of hexamethyldisiloxane, 85.8 wt% of octamethylcyclotetrasiloxane and 12.44 wt% of trimethylsiloxy terminated methylhydrogen polysiloxane 1 as described in US20060264602A1 and art cited therein.

### SiH Siloxane 10: (CH₃)₃SiO[(CH₃)₂Si)]₃[H(CH₃)SiO]₃Si(CH₃)₃

Prepare by trifluoromethane sulfonic acid catalyzed equilibration of 25.13 wt% of hexamethyldisiloxane, 36.63 wt% of octamethylcyclotetrasiloxane and 38.24 wt% of trimethylsiloxy terminated methylhydrogen polysiloxane 1 as described in US20060264602A1 and art cited therein.

### Alkyl Methyl Siloxane Samples

### Sample 1: (CH₃)₃SiO[(CH₃)₂Si)]₃[(C₆H₁₃)(CH₃)SiO]₆Si(CH₃)₃

Into a 3-neck round bottom flask add 246.2 grams (g) of 1-hexene and 78.5 milligrams (mg) of Pt-47D Catalyst at 25° C. under nitrogen purge. While stirring, add 300.0 g SiH Siloxane 4 dropwise at 70° C. while controlling addition to keep the temperature in the range of 70-80° C. Continue stirring for 4 hours after the addition is complete. Distill the resulting mixture to remove residual 1-hexene. The remaining material is Sample 1.

### Sample 2: (CH₃)₃SiO[(CH₃)₂Si)]₃[(C₈H₁₇)(CH₃)SiO]₆Si(CH₃)₃

Into a 3-neck round bottom flask add 328.25 g of 1-octene and 78.5 mg of Pt-47D Catalyst at 25° C. under nitrogen purge. While stirring, add 300.0 g SiH Siloxane 4 dropwise at 70° C. while controlling addition to keep the temperature in the range of 70-80° C. Continue stirring for 4 hours after the addition is complete. Distill the resulting mixture to remove residual 1-octene. The remaining material is Sample 2.

### Sample 3: (CH₃)₃SiO[(CH₃)₂Si)]₃[(C₁₂H₂₅)(CH₃)SiO]₆Si(CH₃)₃

Into a 3-neck round bottom flask add 492.7 g of 1-dodecene and 78.5 mg of Pt-47D Catalyst at 25° C. under nitrogen purge. While stirring, add 300.0 g SiH Siloxane 4 dropwise at 70° C. while controlling addition to keep the temperature in the range of 70-80° C. Continue stirring for 4 hours after the addition is complete. Wash the reaction product three times with 100 milliliters (mL) of petroleum ether to remove residual 1-dodecene. Then, distill the resulting mixture to remove residual petroleum ether. The remaining material is Sample 3.

### Sample 4: (CH₃)₃SiO[(CH₃)₂Si)]₃[(C₁₄H₂₉)(CH₃)SiO]₆Si(CH₃)₃

Into a 3-neck round bottom flask add 574.4 g of 1-tetradecene and 78.5 mg of Pt-47D Catalyst at 25° C. under nitrogen purge. While stirring, add 300.0 g SiH Siloxane 4 dropwise at 70° C. while controlling addition to keep the temperature in the range of 70-80° C. Continue stirring for 4 hours after the addition is complete. Wash the reaction product three times with 100 mL of petroleum ether to remove residual 1-tetradecene. Then, distill the resulting mixture to remove residual petroleum ether. The remaining material is Sample 4.

### Sample 5: (CH₃)₃SiO[(CH₃)₂Si)]₃[(C₁₆H₃₃)(CH₃)SiO]₆Si(CH₃)₃

Into a 3-neck round bottom flask add 657.0 g of 1-hexadecene and 78.5 mg of Pt-47D Catalyst at 25° C. under nitrogen purge. While stirring, add 300.0 g SiH Siloxane 4 dropwise at 70° C. while controlling addition to keep the temperature in a range of 70-80° C. Continue stirring for 4 hours after the addition is complete. The resulting material is Sample 5.

Sample 5 has a boiling point that is greater than 250° C., Kinematic Viscosity at 25° C. of 45 mm²/s, melting point of 15-20° C., flash point of greater than 200° C., a saturated water absorption of less than 300 weight parts per million weight parts sample fluid, is transparent and colorless, low toxicity risk, zero (or approximately zero) global warming potential, zero (or approximately zero) ozone depletion potential and shows negligible indication of degradation during use.

### Sample 6: (CH₃)₃SiO[(CH₃)₂Si)]₃[(C₁₈H₃₇)(CH₃)SiO]₆Si(CH₃)₃

Into a 3-neck round bottom flask add 369.3 g of 1-Octadecene and 65.0 mg of Pt-47D Catalyst at 25° C. under nitrogen purge. While stirring, add 150.0 g SiH Siloxane 1 dropwise at 70° C. while controlling addition to keep the temperature in the range of 70-80° C. Continue stirring for 4 hours after the addition is complete . The resultant product is a wax at 25° C. so it is not suitable as a cooling fluid. This establishes that the R group in chemical structure (I) must contain fewer than 18 carbon atoms.

### Sample 7: (CH₃)₃SiO[(CH₃)₂Si)]₂₂[(C₈H₁₇)(CH₃)SiO]₂Si(CH₃)₃

Into a 3-neck round bottom flask add 44.3 g of 1-Octene and 78.5 mg of Pt-47D Catalyst at 25° C. under nitrogen purge. While stirring, add 300.0 g SiH Siloxane 5 dropwise at 70° C. while controlling addition to keep the temperature in the range of 70-80° C. Continue stirring for 4 hours after the addition is complete . Distill the resulting product to reduce residual 1-octene to less than 2 wt% of the product composition.

### Sample 8: (CH₃)₃SiO[(CH₃)₂Si)]₃[(C₆H₁₃)(CH₃)SiO]_{4.5}[(C₁₄H₂₉)(CH₃)SiO]_{1.5}Si(CH₃)₃

Into a 3-neck round bottom flask add 114.9 g of 1-tetradecene and 78.5 mg of Pt-47D Catalyst at 25° C. under nitrogen purge. While stirring, add 300.0 g SiH Siloxane 4 dropwise at 70° C. while controlling addition to keep the temperature in a range of 70-80° C. Continue stirring for 2 hours after the addition is complete. Then, add 196.9 g of 1-hexene dropwise into the flask at 60° C. under nitrogen purge and maintain the solution at 70° C. for 2 hours after the addition is complete. Distill the resulting mixture to remove residual 1-hexene. The remaining material is Sample 8.

### Sample 9: (CH₃)₃SiO[(CH₃)₂Si)]₃[(C₆H₁₃)(CH₃)SiO]₃[(C₁₄H₂₉)(CH₃)SiO]₃Si(CH₃)₃

Into a 3-neck round bottom flask add 229.8 g of 1-tetradecene and 78.5 mg of Pt-47D Catalyst at 25° C. under nitrogen purge. While stirring, add 300.0 g SiH Siloxane 4 dropwise at 70° C. while controlling addition to keep the temperature in a range of 70-80° C. Continue stirring for 2 hours after the addition is complete. Then, add 147.7 g of 1-hexene dropwise into the flask at 60° C. under nitrogen purge and maintain the solution at 70° C. for 2 hours after the addition is complete. Distill the resulting mixture to remove residual 1-hexene. The remaining material is Sample 9.

### Sample 10: (CH₃)₃SiO[(CH₃)₂Si)]₃[(C₆H₁₃)(CH₃)SiO]_{1.5}[(C₁₄H₂₉)(CH₃)SiO]_{4.5}Si(CH₃)₃

Into a 3-neck round bottom flask add 344.6 g of 1-tetradecene and 78.5 mg of Pt-47D Catalyst at 25° C. under nitrogen purge. While stirring, add 300.0 g SiH Siloxane 4 dropwise at 70° C. while controlling addition to keep the temperature in a range of 70-80° C. Continue stirring for 2 hours after the addition is complete. Then, add 98.5 g of 1-hexene dropwise into the flask at 60° C. under nitrogen purge and maintain the solution at 70° C. for 2 hours after the addition is complete. Distill the resulting mixture to remove residual 1-hexene. The remaining material is Sample 10.

### Sample 11: (CH₃)₃SiO[(CH₃)₂Si)]₃[(C₈H₁₇)(CH₃)SiO]₃[(C₁₄H₂₉)(CH₃)SiO]₃Si(CH₃)₃

Into a 3-neck round bottom flask add 344.7 g of 1-tetradecene and 78.5 mg of Pt-47D Catalyst at 25° C. under nitrogen purge. While stirring, add 300.0 g SiH Siloxane 4 dropwise at 70° C. while controlling addition to keep the temperature in a range of 70-80° C. Continue stirring for 2 hours after the addition is complete. Then, add 131.3 g of 1-octene dropwise into the flask at 60° C. under nitrogen purge and maintain the solution at 70° C. for 2 hours after the addition is complete. Distill the resulting mixture to remove residual 1-octene. The remaining material is Sample 11.

### Sample 12: (CH₃)₃SiO[(CH₃)₂Si)]₃[(C₁₀H₂₁)(CH₃)SiO]₅Si(CH₃)₃

Into a 3-neck round bottom flask add 410.6 g of 1-Decene and 78.5 mg of Pt-47D Catalyst at 25° C. under nitrogen purge. While stirring, add 300.0 g SiH Siloxane 10 dropwise at 70° C. while controlling addition to keep the temperature in the range of 70-80° C. Continue stirring for 4 hours after the addition is complete. Wash the reaction product three times with 100 milliliters (mL) of petroleum ether to remove residual 1-Decene. Then, distill the resulting mixture to remove residual petroleum ether. The remaining material is Sample 12.

### Sample 13: (CH₃)₃SiO[(CH₃)₂Si)]₁₆[(C₆H₁₃)(CH₃)SiO]₃₈Si(CH₃)₃

Into a 3-neck round bottom flask add 100.0 g of 1-hexene and 36.0 mg of Pt-47D Catalyst at 25° C. under nitrogen purge. While stirring, add 100 g SiH Siloxane 6 dropwise at 70° C. while controlling addition to keep the temperature in a range of 70-80° C. Continue stirring for 4 hours after the addition is complete. Distill the resulting mixture to remove residual 1-hexene. The remaining material is Sample 13.

### Sample 14: (CH₃)₃SiO[(CH₃)₂Si)]₃₅[(C₈H₁₇)(CH₃)SiO]₃₅Si(CH₃)₃

Into a 3-neck round bottom flask add 109.4 g of 1-octene and 36.0 mg of Pt-47D Catalyst at 25° C. under nitrogen purge. While stirring, add 100 g SiH Siloxane 7 dropwise at 70° C. while controlling addition to keep the temperature in a range of 70-80° C. Continue stirring for 4 hours after the addition is complete. Distill the resulting mixture to remove residual 1-octene. The remaining material is Sample 14.

### Sample 15: (CH₃)₃SiO[(CH₃)₂Si)]₂₅[(C₈H₁₇)(CH₃)SiO]₅₅Si(CH₃)₃

Into a 1000-milliliter 3-neck round bottom flask equipped with a reflux condenser, stirring bar, thermometer and addition funnel add 280.0 g of SiH Siloxane 8 and 110 mg Pt-47D Catalyst. Under a nitrogen purge and while stirring add dropwise 486.0 g 1-octene while maintaining the temperature in a range of 70-90° C. Continue stirring for 4 hours at 80° C. after the addition is complete. Strip the reaction product under vacuum for 3 hours at 150° C. to remove excess 1-octene, its isomers and low volatile cyclic siloxanes. Filter the resulting product with a Zeta-Plus filter to achieve Sample 15.

### Sample 16: (CH₃)₃SiO[(CH₃)₂Si)]₈₄[(C₈H₁₇)(CH₃)SiO]₁₄Si(CH₃)₃

Into a 1000-milliliter 3-neck round bottom flask equipped with a reflux condenser, stirring bar, thermometer and addition funnel add 546.0 g of SiH Siloxane 9 and 110 mg Pt-47D Catalyst. Under a nitrogen purge and while stirring add dropwise 180.0 g 1-octene while maintaining the temperature in a range of 70-90° C. Continue stirring for 4 hours at 80° C. after the addition is complete. Strip the reaction product under vacuum for 3 hours at 150° C. to remove excess 1-octene, its isomers and low volatile cyclic siloxanes. Filter the resulting product with a Zeta-Plus filter to achieve Sample 16.

### Sample 17: (CH₃)₃SiO[(CH₃)₂Si)]₃[(CH₂C(CH)₃-Ph)(CH₃)SiO]₃Si(CH₃)₃

Into a 1000-milliliter 3-neck round bottom flask equipped with a reflux condenser, stirring bar, thermometer and addition funnel add 351.0 g of SiH Siloxane 10 and 110 mg Pt-47D Catalyst. Under a nitrogen purge and while stirring add dropwise 299.0 g alpha-methyl styrene while maintaining the temperature in a range of 70-90° C. Continue stirring for 4 hours at 80° C. after the addition is complete. Add to the reaction mixture another 135.0 g of alpha-methyl styrene and 330 mg of Pt-47D Catalyst while maintaining at 80° C. for 4 hours. Strip under vacuum for 3 hours at 150° C. to remove excess alpha-methyl styrene and low volatile cyclic siloxanes. Filter the with a Zeta-Plus filter to achieve Sample 17.

### Sample 18: An 80/20 By-Weight Blend of Sample 1 and Sample 13

Mix 160 g of Sample 1 with 40 g of Sample 13 using a magnetic stirring bar for 30 minutes to obtain a transparent fluid, which is Sample 18.

### Sample 19: An 80/20 By-Weight Blend of Sample 2 and Sample 14

Mix 160 g of Sample 2 with 40 g of Sample 14 using a magnetic siring bar for 30 minutes to obtain a transparent fluid, which is Sample 19.

### Sample 20: (CH₃)₃SiO[(C₈H₁₇)(CH₃)SiO]₈Si(CH₃)₃ NOTE: m=0 and n=8

Into a 3-neck round bottom flask add 175.0 g of 1-octene and 36.0 mg of Pt-47D Catalyst at 25° C. under nitrogen purge. While stirring, add 100.0 g SiH Siloxane 3 dropwise at 70° C. while controlling addition to keep the temperature in a range of 70-80° C. Continue stirring for 4 hours after the addition is complete. Distill the resulting mixture to remove residual 1-octene. The remaining material is Sample 20.

### Sample 21: (CH₃)₃SiO[(C₁₄H₂₉)(CH₃)SiO]₈Si(CH₃)₃ NOTE: m=0 and n=8

Into a 3-neck round bottom flask add 153.0 g of 1-tetradecene and 18.0 mg of Pt-47D Catalyst at 25° C. under nitrogen purge. While stirring, add 50.0 g SiH Siloxane 3 dropwise at 70° C. while controlling addition to keep the temperature in a range of 70-80° C. Continue stirring for 4 hours after the addition is complete. The remaining material is Sample 21.

### Sample 22: (CH₃)₃SiO(C₈H₁₇)(CH₃)SiOSi(CH₃)₃ NOTE: m=0 and n=1

This material is commercially available as TM-081 from Gelest.

### Sample Characterization

Characterize each of the 19 Samples for viscosity, flash point, SiH residue and hydrocarbon residue using the procedures described hereinabove. Further characterize with the Samples are liquid at 25° C. and compatibility of the Samples with silicone rubber and EPDM rubber using the following Compatibility Test procedure. Results of the characterization of the Samples are in Table 3, below.

Compatibility Test. Cut test samples of EPDM rubber and silicone rubber that are each 5 centimeters long, 0.5 centimeters wide and 2 millimeters thick. Record the initial length and initial weight of each sample material. In a container, fully submerge the test sample in one of the fluids. Seal the container and heat to 50° C. Store the container for four months at 50° C. and then remove the samples, blot dry with absorbing paper on both sides of the test sample. Record the sample length and weight. Determine the change in length and weight relative to before submersion. An increase in length of more than 15% (Final Length of more than 115% relative to initial length) constitutes “significant swell”. An increase in weight of more than 50% (Final Weight of greater than 150% relative to initial weight) constitutes “significant imbibing”. Significant swelling and/or significant swelling results in a failure of the Compatibility Test.

For comparison purposes, reference fluids of polyalphaolefin, mineral oil, polydimethylsiloxane (PDMS), and Fluorocarbon Fluid 1 are also characterized in the Compatibility Test with the following results in Table 2:

TABLE 2

| Test Fluid | Test Material | Final Length as percent of initial length | Final weight as percent of initial weight | Pass/Fail |
|---|---|---|---|---|
| Mineral Oil | Silicone Rubber | 101.2 | 102.7 | Pass |
| | EPDM Rubber | 121.2 | 148.8 | Fail |
| PAO Oil | Silicone Rubber | 100.7 | 102.3 | Pass |
| | EPDM Rubber | 117.2 | 139.8 | Fail |
| Fluorocarbon Fluid 1 | Silicone Rubber | 100.4 | 99.9 | Pass |
| | EPDM Rubber | 99.9 | 99.9 | Pass |
| PDMS | Silicone Rubber | 128.6 | 200.0 | Fail |
| | EPDM Rubber | 97.1 | 94.7 | Pass |

Overall, both mineral oil and PAO oil Fail due to significant swell of EPDM and PDMS fails for both significant swell and significant imbibing of Silicone Rubber.

Table 3 provides characterization results for Samples 1-22. To receive an Overall Pass, the Sample must pass all the characterization requirements:
Fluid at 25° C. = yes
Viscosity at 25° C. = <100 mm²/s
Flash Point >150° C.
SiH Residue <10 ppm
Hydrocarbon Residue <20 wt%
Compatibility Test = Pass for both Silicone Rubber and EPDM Rubber.

The following Samples receive an overall Fail:

Sample 6: This Sample is a wax at 25° C., demonstrating that the R group in chemical structure (I) must contain fewer than 18 carbon atoms.

Sample 7: This Sample demonstrates that the m should be less than 22.

Samples 13-16: These Samples demonstrate that when the sum of subscripts m and n (that is “m+n”) is greater than 54 the viscosity becomes too high.

Samples 20-22: These Samples demonstrate the need for m to be greater than zero.

TABLE 3

| Sample | Fluid at 25° C.? | Viscosity at 25° C. (mm²/s) | Flash Point (°C) | SiH Residue (ppm) | Hydrocarbon Residue (wt%) | Compatibility Test (Silicone Rubber) | | | Compatibility Test (EPDM Rubber) | | | Overall Pass or Fail |
|---|---|---|---|---|---|---|---|---|---|---|---|---|
| | | | | | | Final Length (%) | Final Weight (%) | P/F | Final Length (%) | Final Weight (%) | P/F | |
| 1 | Yes | 25 | 214 | 0.4 | 0.53 | 99.5 | 101.1 | P | 99.6 | 98.9 | P | Pass |
| 2 | Yes | 28 | 218 | 0.4 | 2.87 | 100.7 | 102.0 | P | 99.3 | 97.4 | P | Pass |
| 3 | Yes | 48 | 274 | 0.8 | 8.55 | 102.5 | 104.8 | P | 98.3 | 96.6 | P | Pass |
| 4 | Yes | 55 | 220 | 0.9 | 4.81 | 98.9 | 102.8 | P | 98.3 | 96.6 | P | Pass |
| 5 | Yes | 45 | 214 | 0.9 | 11.8 | 102.6 | 106.6 | P | 104.3 | 107.6 | P | Pass |
| 6 | NO^{#} | NT^{∗} | NT^{∗} | NT^{∗} | NT^{∗} | NT^{∗} | NT^{∗} | NT^{∗} | NT^{∗} | NT^{∗} | NT^{∗} | Fail |
| 7 | Yes | 27 | >300 | 0.3 | 1.62 | 115.7^{#} | 154^{#} | F | 96.0 | 91.5 | P | Fail |
| 8 | Yes | 38 | 198 | <0.1 | 1.34 | 100.4 | 100.2 | P | 99.8 | 99.7 | P | Pass |
| 9 | Yes | 40 | 234 | 3.5 | 3.89 | 99.5 | 99.2 | P | 99.4 | 98.8 | P | Pass |
| 10 | Yes | 53 | 214 | 1.0 | 3.65 | 100.1 | 99.8 | P | 99.4 | 99.4 | P | Pass |
| 11 | Yes | 48 | 208 | 0.4 | 3.66 | 99.7 | 99.8 | P | 99.7 | 99.3 | P | Pass |
| 12 | Yes | 50 | 230 | 0.5 | 3.63 | 113.0 | 134.0 | P | 104.0 | 101.0 | P | Pass |
| 13 | Yes | 338^{#} | NT^{∗} | NT^{∗} | NT^{∗} | 101.4 | 101.5 | P | 97.8 | 95.0 | P | Fail |
| 14 | Yes | 214^{#} | NT^{∗} | NT^{∗} | NT^{∗} | 100.6 | 102.6 | P | 97.8 | 95.7 | P | Fail |
| 15 | Yes | 747^{#} | NT^{∗} | NT^{∗} | NT^{∗} | 99.4 | 99.6 | P | 98.1 | 95.8 | P | Fail |
| 16 | Yes | 229^{#} | NT^{∗} | NT^{∗} | NTv | 106.4 | 116.7 | P | 99.0 | 97.8 | P | Fail |
| 17 | Yes | 62 | 208 | 1.6 | 1.51 | 107.9 | 118.6 | P | 99.4 | 101.4 | P | Pass |
| 18 | Yes | 87 | 217 | 1.7 | 0.99 | 113.7 | 118.9 | P | 102.6 | 102.1 | P | Pass |
| 19 | Yes | 65 | 225 | 1.9 | 2.88 | 107.1 | 118.5 | P | 98.8 | 99.7 | P | Pass |
| 20 | Yes | 101^{#} | NT^{∗} | 47^{#} | NT^{∗} | 99.7 | 99.4 | P | 99.6 | 100.3 | P | Fail |
| 21 | Yes | 125 | NT^{∗} | 236^{#} | NT^{∗} | 99.3 | 100.0 | P | 100.3 | 99.6 | P | Fail |
| 22 | Yes | 2.85 | <130# | NT^{∗} | NT^{∗} | NT^{∗} | NT^{∗} | NT^{∗} | NT^{∗} | NT^{∗} | NT^{∗} | Fail |

^{∗} NT=not tested. If a Sample fails on one parameter prior to testing the others then further testing is not needed.
# designates a Failing test characteristic.

What is claimed is:

1. A process comprising the step of immersing a device in a cooling fluid, the cooling fluid comprising an alkyl modified silicone oil having the following average chemical structure (I): 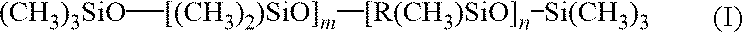
where: R is independently in each occurrence selected from a group consisting of alkyl and substituted alkyl groups where each R group has 6 or more and at the same time 17 or fewer carbon atoms; subscript m has a value of one or higher and at the same time less than 22, subscript n has a value of one or higher, and the sum of m+n is greater than 5 and at the same time less than 50.

2. The process of claim 1, wherein the device is a heat generating device and/or a heat sink affixed to a heat generating device.

3. The process of claim 1, wherein the R group in structure (I) is an alkyl or a phenyl substituted alkyl.

4. The process of claim 1, wherein the cooling fluid comprises less than 20 weight-percent hydrocarbons based on cooling fluid weight.

5. The process of claim 1, wherein the process further includes the steps of cooling the cooling fluid.

6. The process of claim 5, wherein the cooling fluid is circulated around the device, through a cooling unit and then back around the device in a cycle.

7. A liquid immersion cooling system comprising a device in a cooling fluid, the cooling fluid comprising an alkyl modified silicone oil having the following average chemical structure (I): 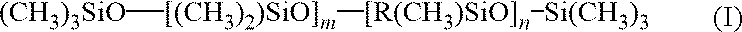
where: R is independently in each occurrence selected from a group consisting of alkyl and substituted alkyl groups where each R group has 6 or more and at the same time 17 or fewer carbon atoms; subscript m has a value of one or higher and at the same time less than 22, subscript n has a value of one or higher, and the sum of m+n is greater than 5 and at the same time less than 50.

8. The liquid immersion cooling system of claim 7, wherein the device is a heat generating device and/or a heat sink affixed to the heat generating device.

9. The liquid immersion cooling system of claim 7, the system further comprising a cooler that removes heat from the cooling fluid.

10. The liquid immersion cooling system of claim 7, wherein the system further comprises a circulating component that causes the cooling fluid flows around the device immersed in the cooling fluid.
